(19) United States
(12) Patent Application Publication
(10) Pub. No.: US 2016/0005843 A1
(43) Pub. Date: Jan. 7, 2016

(54) SEMICONDUCTOR DEVICE AND MANUFACTURING METHOD THEREOF

(71) Applicants: Yasuhiro HIRABAYASHI, Toyota-shi (JP); Toru ONISHI, Nagoya-shi (JP); Katsuhiko NISHIWAKI, Toyota-shi (JP); Jun SAITO, Nagoya-shi (JP)

(72) Inventors: Yasuhiro HIRABAYASHI, Toyota-shi (JP); Toru ONISHI, Nagoya-shi (JP); Katsuhiko NISHIWAKI, Toyota-shi (JP); Jun SAITO, Nagoya-shi (JP)

(73) Assignee: TOYOTA JIDOSHA KABUSHIKI KAISHA, Toyota-shi, Aichi-ken (JP)

(21) Appl. No.: 14/766,887

(22) PCT Filed: Feb. 12, 2013
(86) PCT No.: PCT/JP2013/053245

§ 371 Date: Aug. 10, 2015

(51) Int. Cl. H01L 29/739; H01L 21/265; H01L 29/08; H01L 29/66; H01L 29/417; H01L 21/306; H01L 29/06

(52) U.S. Cl. CPC H01L 29/7397; H01L 21/30604; H01L 21/30625; H01L 21/26513; H01L 29/0619; H01L 29/66348; H01L 29/41708; H01L 29/0821; H01L 29/0649

(57) ABSTRACT

By using an SOI substrate in which a front surface-side semiconductor layer, an insulating layer, and a back surface-side semiconductor layer are laminated in this order, vertical semiconductor devices are mass-produced. A process to be executed on a front surface of the SOI substrate is executed on the front surface. A back surface of the SOI substrate is etched so that the back surface-side semiconductor layer and the insulating layer are removed and a back surface of the front surface-side semiconductor layer is exposed. A process to be executed on the exposed back surface of the front surface-side semiconductor layer is executed on the back surface. A thickness of the front surface-side semiconductor layer of the SOI substrate can be accurately controlled, and the semiconductor devices having a semiconductor layer with the same thickness as the thickness of the front surface-side semiconductor layer are mass-produced.

### TECHNICAL FIELD

This specification discloses a semiconductor device and a manufacturing method thereof. The specification particularly relates to a vertical semiconductor device which is manufactured by thinning a semiconductor substrate and a manufacturing method thereof. The vertical semiconductor device is a semiconductor device in which electric current flows between a surface electrode and a rear electrode formed in the semiconductor substrate.

### BACKGROUND ART

A performance of a vertical semiconductor device is affected by a thickness of a semiconductor substrate. In most cases, thinning of the semiconductor substrate improves the performance of the semiconductor device. The thinned semiconductor substrate easily breaks and deflects, and thus its handling is difficult. For this reason, it is difficult to execute a semiconductor manufacturing process on the thinned semiconductor substrate and manufacture a semiconductor device. This therefore had caused widespread use of a technique for performing a process, which is supposed to be performed on a front surface of a semiconductor substrate, on the front surface of the semiconductor substrate which is not yet thinned, fixing a reinforcement member to the processed front surface of the semiconductor substrate, polishing a back surface of the semiconductor substrate whose front surface has been reinforced so as to thin the semiconductor substrate, performing a process, which is supposed to be performed on a back surface of the semiconductor substrate, to the back surface of the thinned semiconductor substrate, and peeling the reinforcement member from the front surface of the semiconductor substrate.

### CITATION LIST

### Patent Documents

Patent Document 1: Japanese Patent Application Publication No. 2009-064825

Patent Document 2: Japanese Patent Application Publication No. 2005-317570

Patent Document 3: Japanese Patent Application Publication No. 2004-088074

Patent Document 4: Japanese Patent Application Publication No. 2000-040773

Patent Document 5: Japanese Patent Application Publication No. 2000-040711

### SUMMARY OF INVENTION

### Technical Problem

In the above manufacturing method, when the back surface of the semiconductor substrate is polished to be thinned, it is difficult to control a thickness of the thinned semiconductor substrate to be at a constant value. When a group of semiconductor devices is mass-produced, the thickness of the thinned semiconductor substrate varies at each time the semiconductor device is manufactured, and variation in the thickness becomes large.

Particularly, the front surface of the semiconductor substrate is not flat at a process stage when processing to be performed on the front surface of the semiconductor substrate is performed, and thus an undulation is occasionally formed on the processed front surface. When the undulation is present on the front surface, the semiconductor substrate easily deflects when processing on a back surface is performed, and the thickness of the semiconductor substrate easily varies even within one semiconductor substrate. When a plurality of semiconductor devices is manufactured from one semiconductor substrate, the variation in the thickness is large even within a same group of semiconductor devices which was manufactured simultaneously.

Further, in the conventional manufacturing method, since the substrate is thinned, wholly with no local consideration, the semiconductor substrate easily breaks and deflects.

This specification discloses a method for mass-producing a group of vertical semiconductor devices where a variation in thickness of a semiconductor substrate is small. This specification further discloses improved techniques obtained by developing the above basic technique. In this improved techniques, a performance of each semiconductor device is made highly stable in a range necessary for securing the performance of the group of semiconductor devices by thinning into a prescribed thickness, and strength of the semiconductor substrate is ensured by not thinning the semiconductor substrate in a range that is not related to the performance of the semiconductor devices. Also in this improved techniques, the basic technique is utilized in the thinning range.

### Solution to Technical Problem

In the basic technique disclosed in this specification, a semiconductor manufacturing process is executed on an SOI substrate. The SOI substrate is a laminated substrate in which a front surface-side semiconductor layer, an insulating layer, and a back surface-side semiconductor layer are laminated in this order, and both the front surface-side semiconductor layer and the back surface-side semiconductor layer are formed of semiconductor materials which include silicon (for example, Si or SiC monociystal). The back surface side is a side which is to be etched for thinning, and the front surface side is a side which still remains after the etching.

In the basic technique disclosed in this specification, a process to be executed on a front surface of the front surface-side semiconductor layer of the SOI substrate is executed on the front surface. Then a back surface of the SOI substrate is etched, and the back surface-side semiconductor layer and the insulating layer in at least a part of an active region formed with a semiconductor structure functioning as a semiconductor device are removed so that a back surface of the front surface-side semiconductor layer is exposed. Thereafter, a process to be executed on the back surface of the front surface-side semiconductor layer of the SOT substrate is executed on the back surface, so that the semiconductor structure necessary for the vertical semiconductor device is manufactured.

In an etching step, the back surface-side semiconductor layer and the insulating layer are removed from at least a part of the active region. That is to say, the back surface-side semiconductor layer and the insulating layer may be removed from entireties of the active region and the other entire region. The back surface-side semiconductor layer and the insulating layer may be removed from the active region, and the back surface-side semiconductor layer and the insulating layer may be allowed to remain in the other region. A necessary performance may in some cases be secured by thinning a part of the active region, and in this case, the back surface-side semiconductor layer and the insulating layer may be removed from the part of the active region.

Prior to the etching step, the back surface of the SOI substrate may be mechanically polished so that the back surface-side semiconductor layer may be thinned. That is to say, an occasion of exposing the back surface of the front surface-side semiconductor layer may be realized by the etching, and a mechanical polishing step may be employed at a process stage prior to the exposing.

In the above manufacturing method, etching is performed on the back surface of the SOI substrate so that the back surface-side semiconductor layer and the insulating layer are removed and the front surface-side semiconductor layer is allowed to remain. The thinned semiconductor substrate is obtained by the front surface-side semiconductor layer that remains after the etching. Depending on an etching technique, a phenomenon that the insulating layer is etched but the front surface-side semiconductor layer is not, etched may be obtained. Due to this, this etching method can prevent the front surface-side semiconductor layer from being thinned from the back surface side. A relationship can be established such that “a thickness of the thinned semiconductor substrate”=“a thickness of the front surface-side semiconductor layer of the SOI substrate”.

The thickness of the front surface-side semiconductor layer of the SOI substrate can be accurately controlled. Contrary to this, the thickness of the thinned semiconductor substrate that is obtained by polishing to thin the back surface of the semiconductor substrate greatly varies. A relationship can be established such that “variation in the thickness of the front surface-side semiconductor layer of the SOI substrate”<“variation in the thickness of the polished and thinned semiconductor substrate”.

According to the above manufacturing method, the above two technical elements are combined so that a group of vertical semiconductor devices with small variation in the semiconductor substrate thickness can be mass-produced.

In a process stage which is prior to the etching step, the mechanical polishing step may be employed so as to perform the thinning. When the process stage of exposing the back surface of the front surface-side semiconductor layer is realized by the etching, the phenomenon that the insulating layer is etched but the front surface-side semiconductor layer is not etched can be obtained, and the relationship can be established such that “the thickness of the thinned semiconductor substrate”=“the thickness of the front surface-side semiconductor layer of the SOI substrate”. By implementing the mechanical polishing step in combination, a time required for the thinning process may be shortened.

In the basic technique disclosed in this specification, the semiconductor substrate is thinned by etching the back surface of the SOI substrate and removing the back surface-side semiconductor layer and the insulating layer, while allowing the front surface-side semiconductor layer to remain. In the basic technique, a phenomenon in which the insulating layer is etched and the front surface-side semiconductor layer is hardly etched, which is brought forth by the etching technique, is utilized. The back surface-side semiconductor layer and the insulating layer may be removed over an entire region of the SOI substrate.

The semiconductor substrate of the vertical semiconductor device is thinned in order to improve the performance of the semiconductor device. A region necessary for improving the performance may not always be the entire region of the semiconductor device. A residual region does not have to be thinned as long as the active region in which the semiconductor structure functioning as the semiconductor device is formed is thinned. The necessary performance may be secured by thinning just a part of the active region, and in this case, the part of the active region may be thinned, and the residual region does not have to be thinned.

The etching technique enables the etching in a limited region. The back surface-side semiconductor layer and the insulating layer are removed in the limited region, and the back surface-side semiconductor layer and the insulating layer can be allowed to remain in a region other than the limited region. Only the region for which the thinning is necessary is thinned, whereas the thick substrate yet to be subjected to the thinning can be allowed to remain in the residual region. When the residual region is not thinned, that portion serves as a reinforcement member so as to contribute to securing of the strength of the semiconductor substrate.

In improved techniques disclosed in this specification, the above two technical elements are combined, and a region necessary for improving the performance is etched to be thinned, but the residual region is not etched. The improved techniques can provide a result such that the back surface-side semiconductor layer and the insulating layer that are not etched to remain and reinforce the thinned front surface-side semiconductor layer. The improved techniques can mass-produce semiconductor devices, each including the region necessary for improving the performance of the semiconductor device being thinned and the range that is not necessary for improving the performance having an enough thickness to prevent breakage and deflection of the semiconductor substrate.

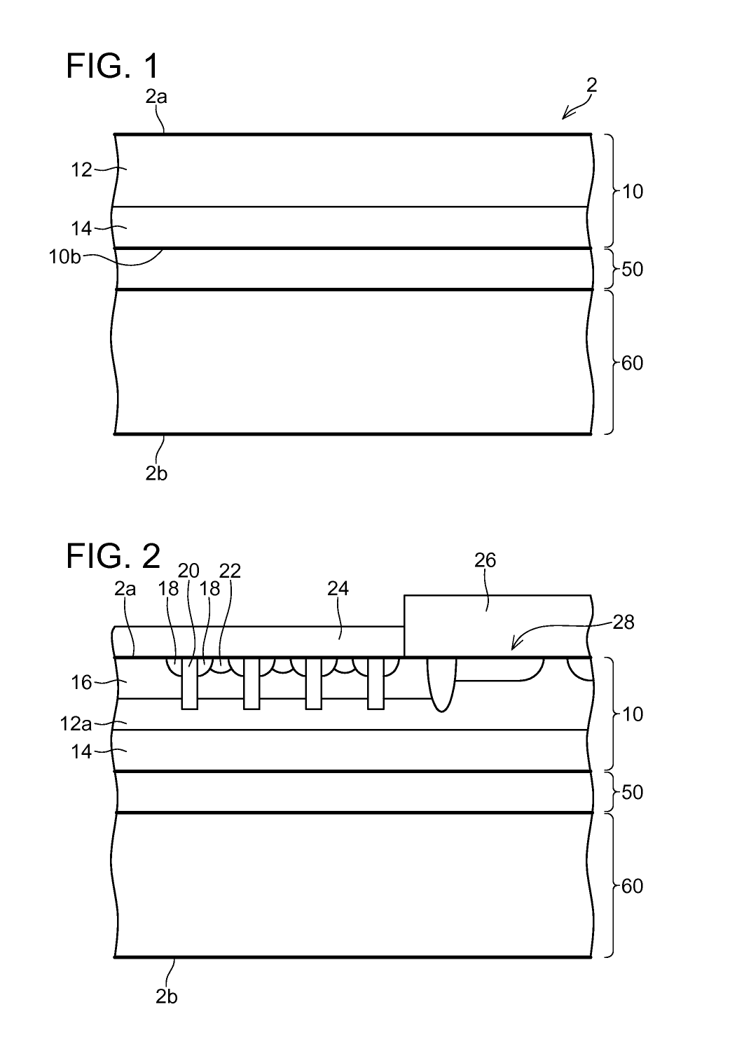

FIG. 1 illustrates a cross-sectional structure of an SOI substrate to be used in a manufacturing method according to an embodiment.

FIG. 2 illustrates a cross-sectional structure at a process stage where necessary processes have been executed on a front surface of the SOI substrate.

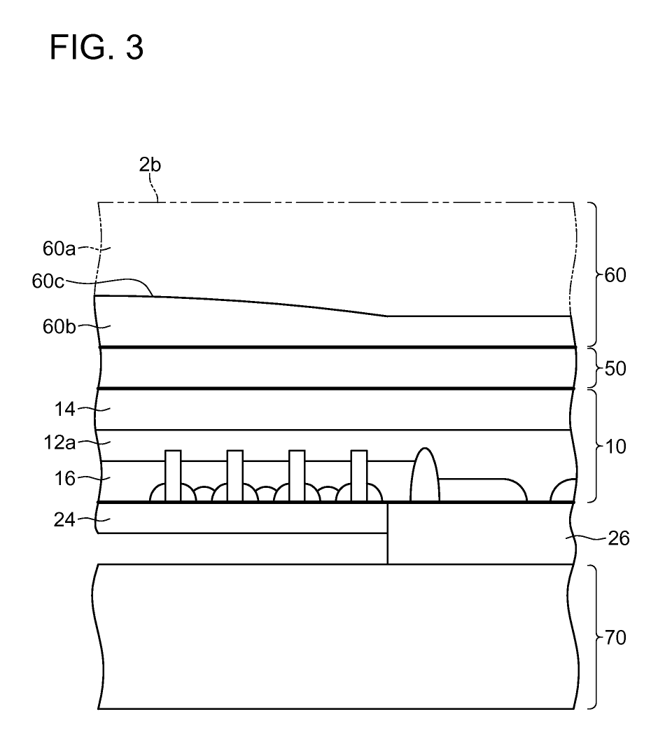

FIG. 3 illustrates a cross-sectional structure at a process stage where a reinforcement member has been fixed to the front surface of the SOI substrate and polishing from a back surface has been performed.

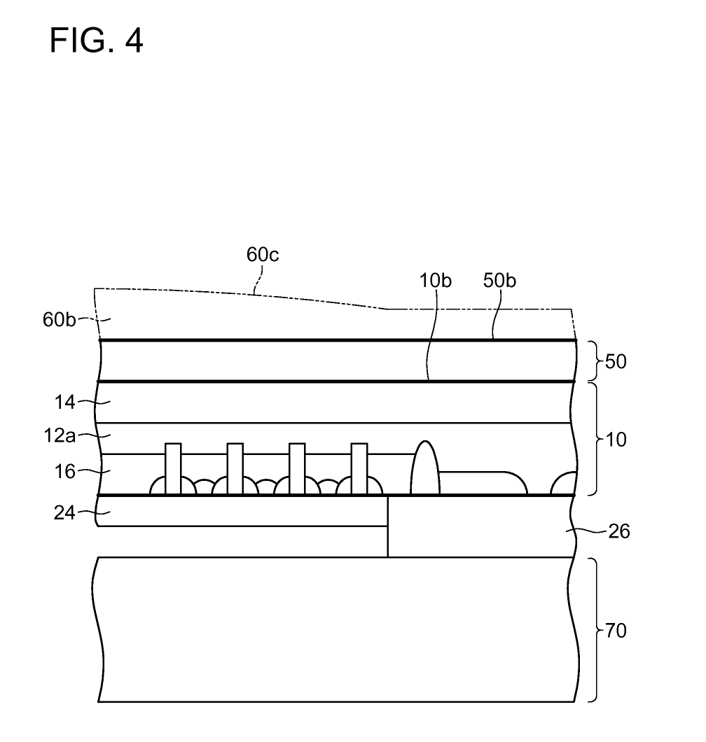

FIG. 4 illustrates a cross-sectional structure at a process stage where a back surface-side semiconductor layer remaining after the polishing and an insulating layer has been exposed.

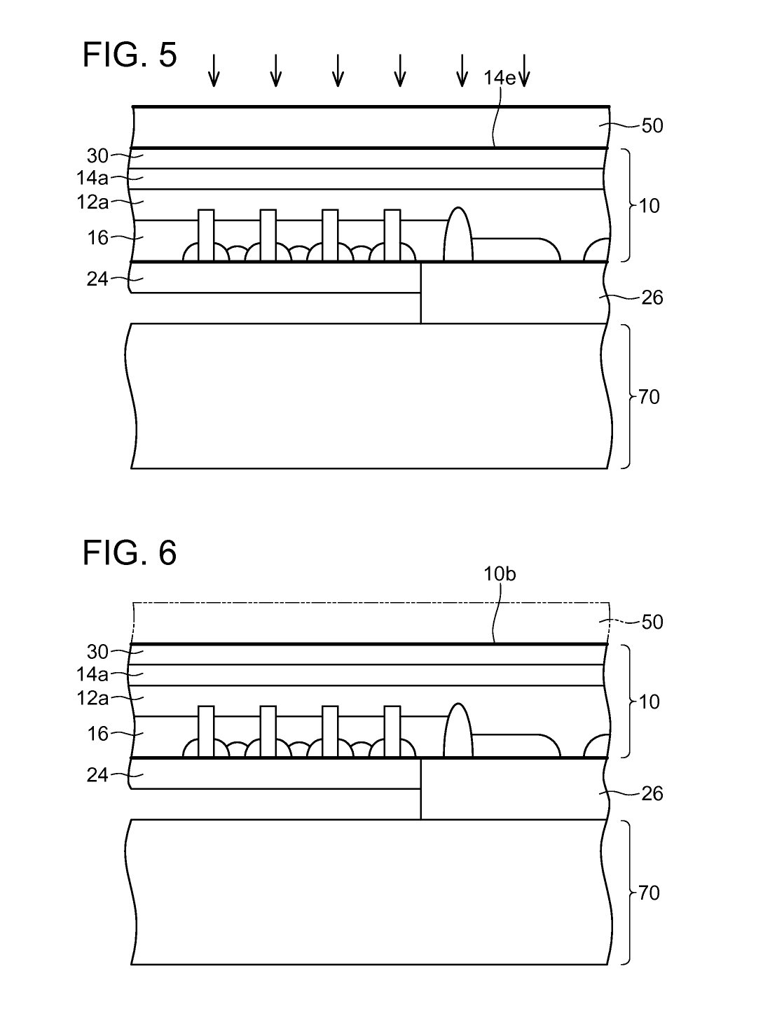

FIG. 5 illustrates a cross-sectional structure at a process stage where ions have been implanted through the insulating layer and a collector region has been formed.

FIG. 6 illustrates a cross-sectional structure at a process stage where the insulating layer has been etched and a back surface of a front face side semiconductor layer has been exposed.

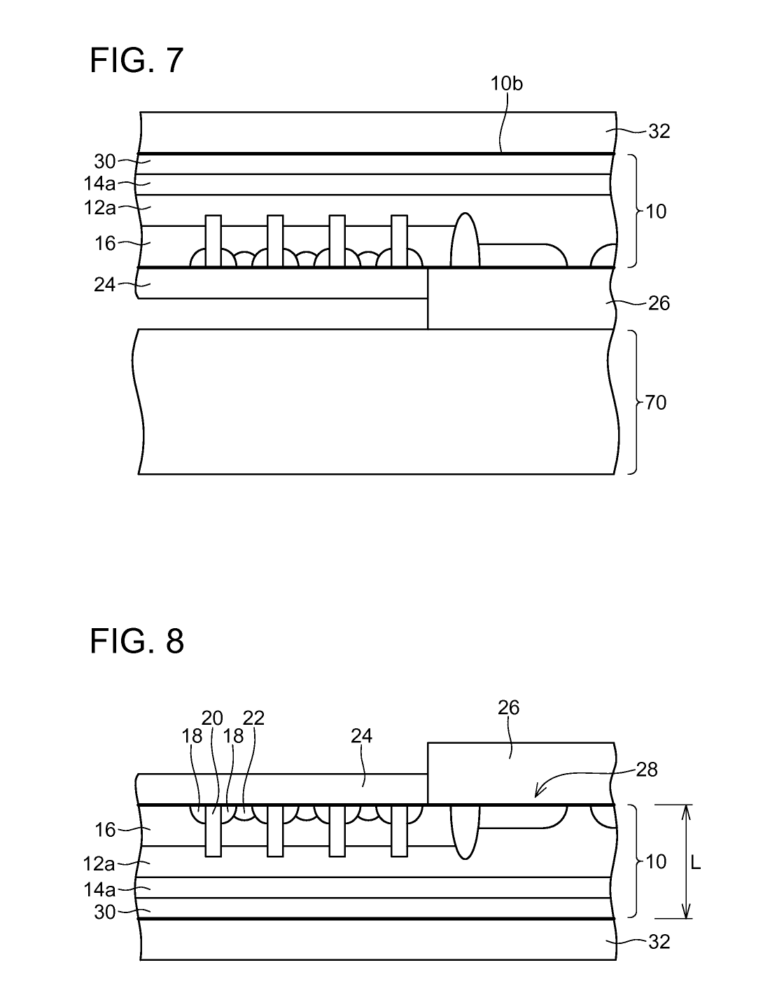

FIG. 7 illustrates a cross-sectional structure at a process stage where a back surface electrode has been formed on the back surface of the front face side semiconductor layer.

FIG. 8 illustrates a cross-sectional structure at a process stage where the reinforcement member has been peeled.

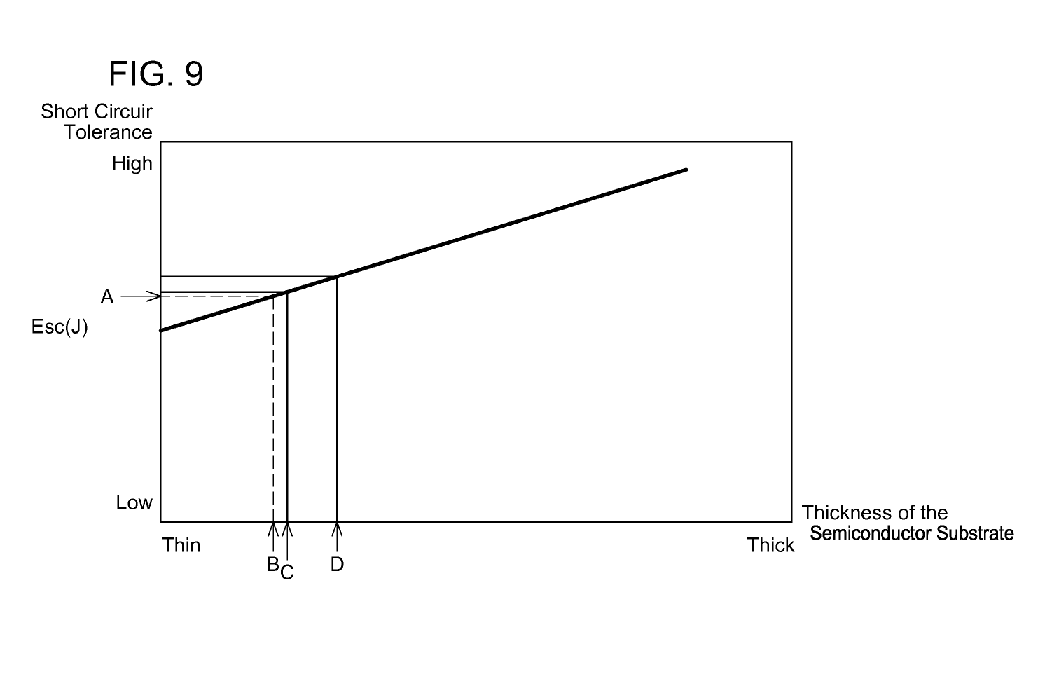

FIG. 9 illustrates a relationship between a thickness of the semiconductor substrate and a short circuit tolerance.

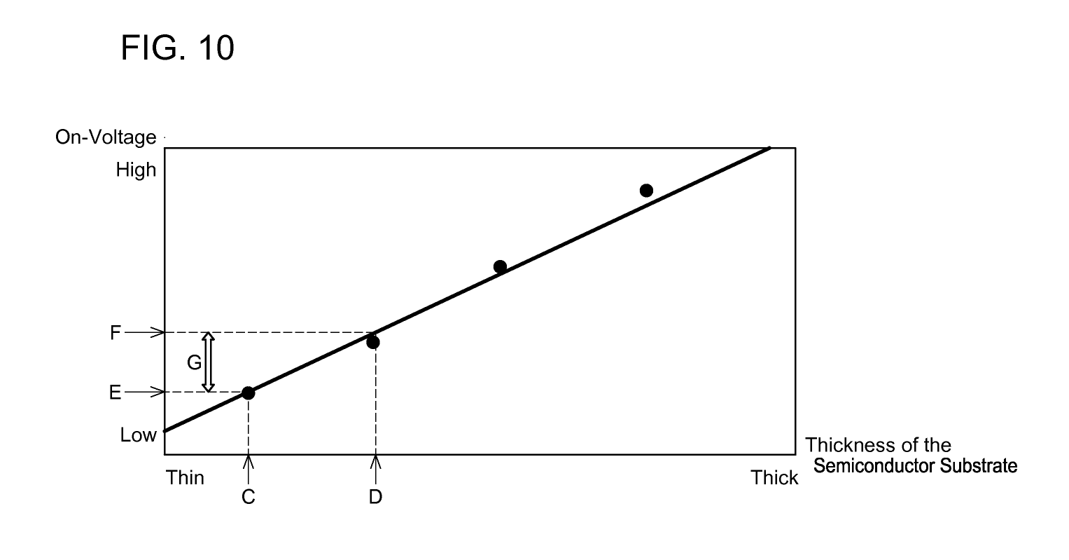

FIG. 10 illustrates a relationship between the thickness of the semiconductor substrate and an on-voltage.

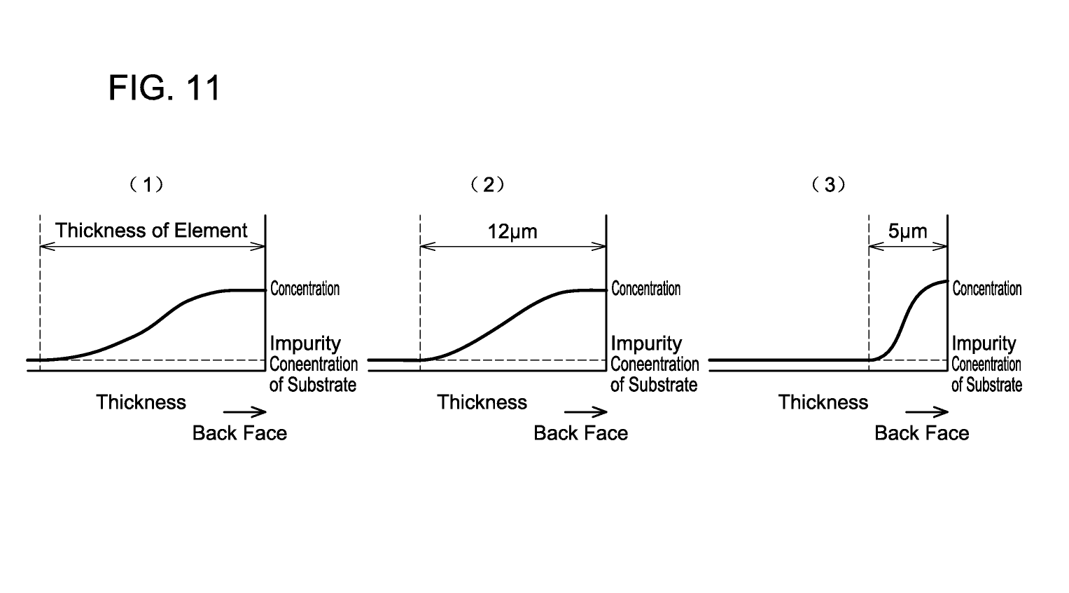

FIG. 11 illustrates relationships between an impurity concentration and a depth in respective processes to be executed on the back surface.

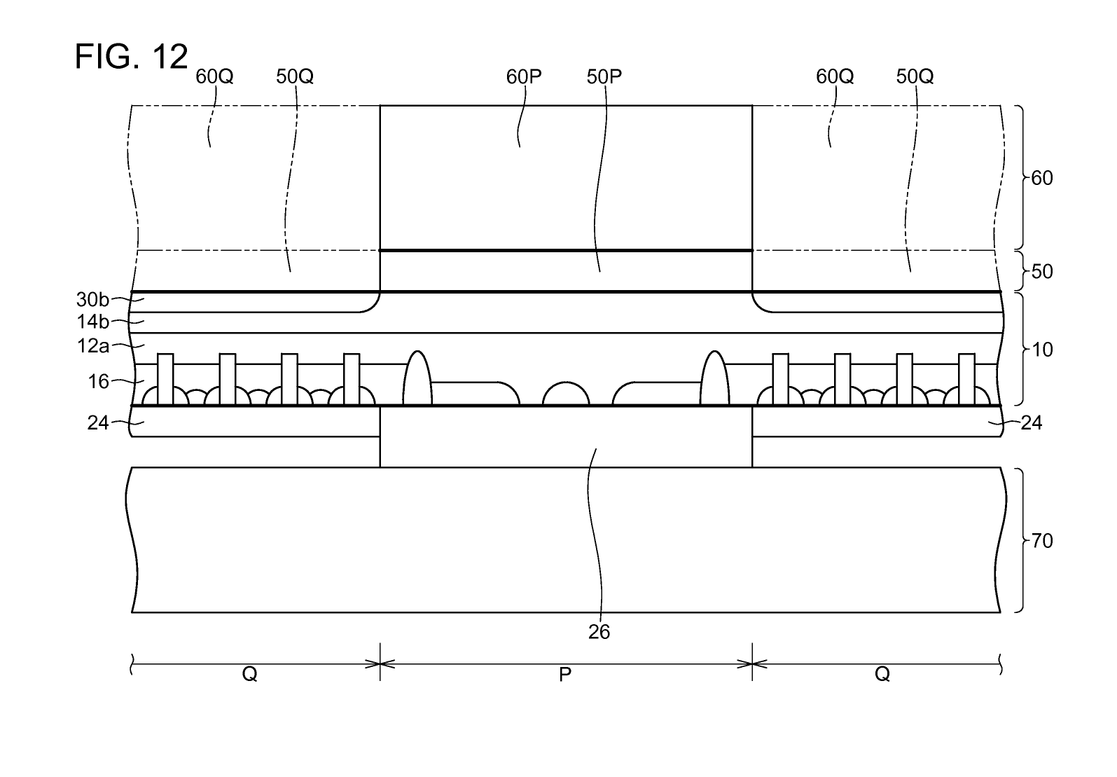

FIG. 12 illustrates a cross-sectional structure at a process stage where a partial region of the back surface-side semiconductor layer has been thinned and a residual portion has not been thinned in a manufacturing method according to an improved embodiment.

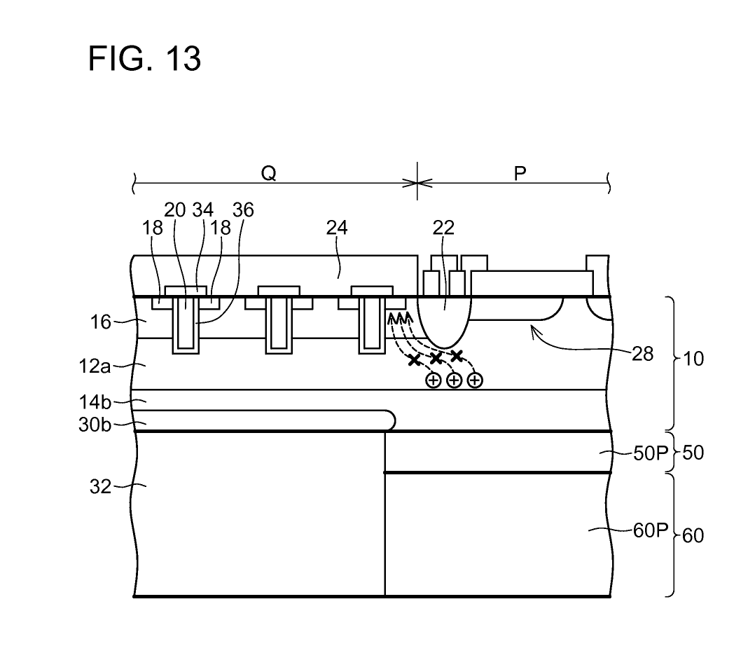

FIG. 13 illustrates a cross-sectional structure of a semiconductor device to be manufactured by the manufacturing method according to the improved embodiment.

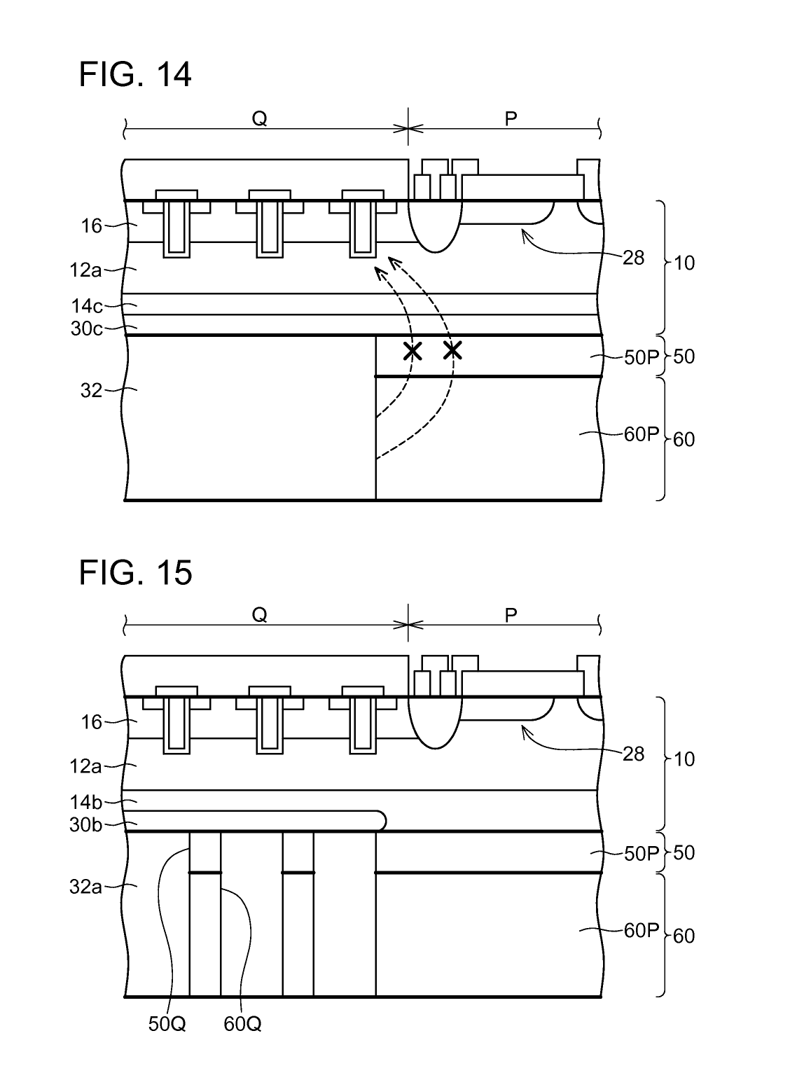

FIG. 14 illustrates a cross-sectional structure of a semiconductor device according to an improved second embodiment.

FIG. 15 illustrates a cross-sectional structure of a semiconductor device according to an improved third embodiment.

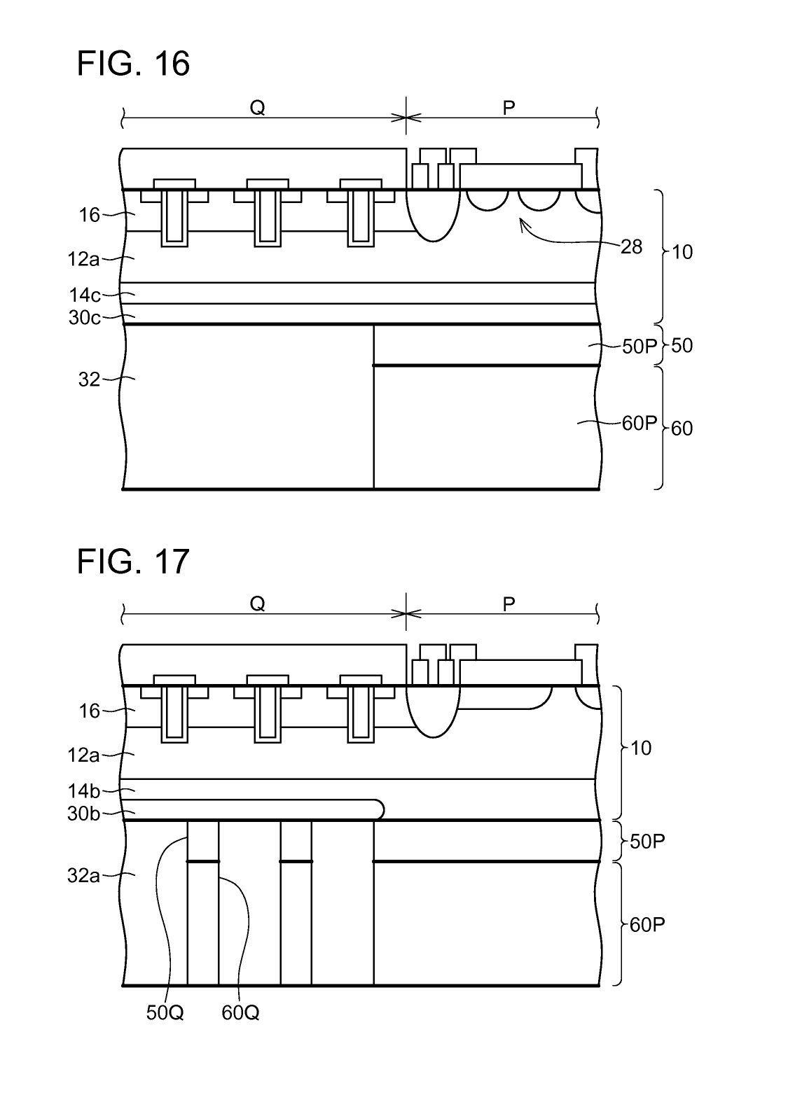

FIG. 16 illustrates a cross-sectional structure of a semiconductor device according to an improved fourth embodiment.

FIG. 17 illustrates a cross-sectional structure of a semiconductor device according to an improved fifth embodiment.

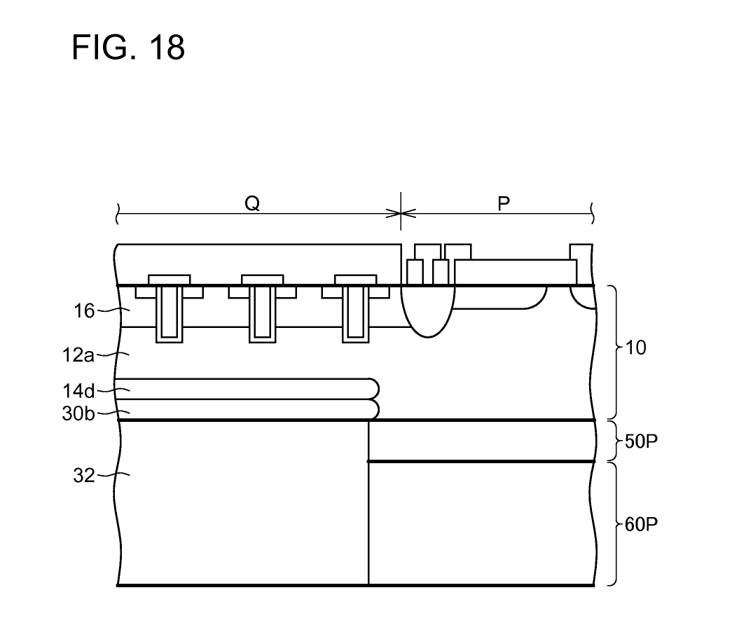

FIG. 18 illustrates a cross-sectional structure of a semiconductor device according to an improved sixth embodiment.

### DESCRIPTION OF EMBODIMENTS

Features of embodiments to be described below are summarized as below
(Feature 1) An SOI substrate, in which a front surface-side semiconductor layer is an n-type Si monocrystal, an insulating layer is a SiO₂ layer, and a back surface-side semiconductor layer is a Si monocrystal, is used.
(Feature 2) The back surface-side semiconductor layer may be of p-type or n-type. There is no limitation to its conductivity type.
(Feature 3) An impurity concentration of the front surface-side semiconductor layer may be adjusted to a concentration that is necessary for a drift region of an IGBT.
(Feature 4) An n-type impurity high-concentration diffusion region is formed in a vicinity of a back surface of the n-type Si monocrystal serving as the front surface-side semiconductor layer.
(Feature 5) An impurity concentration of the n-type impurity high-concentration diffusion region may be adjusted to a concentration necessary for a buffer region of the IGBT.
(Feature 6) P-type impurities may be implanted through the insulating layer so as to cause conversion into the p-type. The impurity concentration thereof may be adjusted to a concentration necessary for a collector region of the IGBT. The p-type impurities may be implanted by energy by which the collector region is formed in a vicinity of a back surface of the n-type impurity high-concentration diffusion region.
(Feature 7) The IGBT may be formed in a region (an active region) surrounded by a peripheral voltage withstanding structure.
(Feature 8) An IGBT and a diode may be formed in the region (the active region) surrounded by the peripheral voltage withstanding structure.
(Feature 9) The collector region may be or may not be formed in a peripheral region.
(Feature 10) The buffer region may be or may not be formed in the peripheral region.
(Feature 11) The back surface-side semiconductor layer and the insulating layer may remain in the peripheral region, and the back surface-side semiconductor layer and the insulating layer may be removed in the active region.
(Feature 12) The back surface-side semiconductor layer and the insulating layer may be removed in a part of the active region, and the back surface-side semiconductor layer and the insulating layer may be allowed to remain in a residual portion of the active region and the peripheral region.
(Feature 13) The peripheral voltage withstanding structure may comprise a RESURF layer.
(Feature 14) The peripheral voltage withstanding structure may comprise a guard ring.

### Embodiments

FIG. 1 illustrates a cross-sectional structure of an SOI substrate 2 before a method for manufacturing a semiconductor device according to a first embodiment is executed. For clear illustration, illustration of hatching is omitted. The SOI substrate 2 comprises a structure where a front surface-side semiconductor layer 10, an insulating layer 50, and a back surface-side semiconductor layer 60 are laminated. The front surface-side semiconductor layer 10 and the back surface-side semiconductor layer 60 are Si monocrystal substrates, and the insulating layer 50 is formed of SiO₂. A thickness of the front surface side semiconductor layer 10 is so thin that it easily breaks and deflects alone, but since the front surface-side semiconductor layer 10 is strengthened by the thick back surface-side semiconductor layer 60, the SOI substrate 2 itself can be easily handled. It should be mentioned herein that a dimension in a thickness direction in the drawings is different from an actual ratio, for the sake of clear illustration.

N-type impurities are introduced into the front surface-side semiconductor layer 10 of the SOI substrate 2. An impurity concentration is matched with a concentration of a drift region of an IGBT that is to be finally manufactured. The n-type impurities of high concentration are introduced into a vicinity of a back surface 10b of the front surface-side semiconductor layer 10. A concentration of an n-type impurity high-concentration introducing region 14 in the vicinity of the back surface is matched with a concentration of a buffer region of the IGBT to be finally manufactured. Further, a depth of the n-type impurity high-concentration introducing region 14 from the back surface 10b is matched with a depth of the buffer region of the IGBT to be finally manufactured. The SOI substrate 2 is manufactured by attaching the front surface-side semiconductor layer 10 and the back surface-side semiconductor layer 60. Since the front surface-side semiconductor layer 10 before the attachment is processed so that the n-type impurity high-concentration introducing region 14 is formed, the impurity concentration and the depth can be freely adjusted. In this embodiment, as described later with reference to FIG. 11, the n-type impurity high-concentration introducing region 14 reaches a depth of approximately 12 μm from the back surface 10b of the front surface-side semiconductor layer 10. A reference number 12 in FIG. 1 represents an n-type impurity low-concentration region that remains after the formation of the n-type impurity high-concentration introducing region 14. A thick line in the drawing represents a boundary between the substrates, and a thin line represents a boundary between regions. The SOI substrate 2 in FIG. 1 may be purchased from substrate manufacturers.

FIG. 2 illustrates a cross-sectional structure in a process stage where necessary processes are performed on a front surface 2a of the SOI substrate 2 (namely, a front surface of the front surface-side semiconductor layer). In this embodiment, the IGBT is manufactured. Therefore, at this process stage, a semiconductor structure on a front surface side that is necessary for realizing the IGBT is manufactured. That is to say; a p-type body region 16, n-type emitter regions 18, trench gate electrodes 20, p-type body contact regions 22, a peripheral voltage withstanding structure 28, an emitter electrode 24, and a protective film 26 are manufactured. The p-type body region 16 is manufactured by implanting p-type impurities into a shallow portion of the n-type impurity low-concentration region 12 from the front surface 2a. In FIG. 2, an n-type impurity low-concentration region that remains even after the formation of the body region 16 is denoted by reference number 12a. The n-type impurity low-concentration region 12a becomes the drift region. In a process stage where a process on the front surface 2a is finished, heights of the emitter electrode 24 and the protective film 26 are different from each other. That is to say, the front surface of the SOI substrate 2 after the front surface process is not flat, but thus undulation is present thereon. Notably, in FIG. 2, illustration of a detailed structure including a gate insulating film that surrounds the trench gate electrodes 20, and an inter-layer insulating film that insulates the trench gate electrodes 20 and the emitter electrode 24, is omitted.

FIG. 3 illustrates the SOI substrate 2 that is vertically inverted. In a process stage of FIG. 3, a reinforcement member 70 is stuck to the front surface of the SOI substrate 2 that has undergone the process stage where the process on the front surface 2a was finished, so as to be prepared for a thinning work to be performed later. Since the front surface of the SOI substrate 2 at the process stage where the process on the front surface 2a has been finished is not flat and the protective film 26 is thicker, the reinforcement member 70 is stuck to the protective film 26. A space remains between the reinforcement member 70 and the emitter electrode 24. When the reinforcement member 70 has been stuck to a front surface of the protective film 26, the back surface-side semiconductor layer 60 is mechanically polished from a back surface 2b of the SOI substrate 2. This polishing step is ended at a state that the back surface-side semiconductor layer 60 has been thinned Reference number 60a in FIG. 3 represents a polished region that has been removed by the polishing, and reference number 60b represents a residual region that remains after the polishing.

As described above, the space remains between the reinforcement member 70 and the emitter electrode 24. When the polishing is performed in that state, the SOI substrate 2 warps. The SOT substrate 2 is polished in this warped state. When the polishing is ended, the SOI substrate 2 is released from the warping state. As a result, a polished surface 60c of the residual region 60b that was flat during the polishing becomes a surface that is undesirably curved upward.

In a conventional manufacturing method, the thinning of a substrate is performed by polishing a back surface of the substrate (it should be however mentioned that the substrate to be polished is not the SOI substrate). For this reason, the warp of the substrate during the polishing directly affects a thickness of the thinned substrate. In the conventional manufacturing method, a phenomenon that the thickness of the substrate is changed depending on a position of the warp in the substrate had occurred. In the conventional manufacturing method, the semiconductor device had to be designed on an assumption that the warp of the substrate during the polishing would make the thickness of the substrate non-uniform. As described later, this had prevented improvement of a performance of a semiconductor device.

In this embodiment, the above problem is addressed by performing the thinning not only by the polishing but also by etching thereafter. FIG. 4 illustrates a state that the residual region 60b that remained after the polishing has been etched and removed. At this process stage, the etching is performed by using an etchant that etches the residual region 60b (Si monocrystal) but hardly etches the insulating layer 50 (SiO₂). When a back surface 50b of the insulating layer 50 is exposed on a back surface of the SOI substrate, the etching is ended. At this process stage, the problem that the warp of the substrate during the polishing makes the polished surface 60c of the residual region 60b be curved is solved. The back surface 50b of the insulating layer 50 exposed on the back surface of the SIDI substrate is flat. The etching may be a wet or dry method as long as the residual region 60b is removed without warping the MN substrate.

In this embodiment, the region denoted by 60a in FIG. 3 is mechanically polished to be removed. Instead of this, an entire thickness of the back surface-side semiconductor layer 60 may be removed by etching. In a case where the insulating layer 50 is thick and the polishing step can be finished within a range of the thickness of the insulating layer 50, the polishing may be performed without allowing the residual region 60b to remain and until the insulating layer 50 is exposed. An important thing is to perform the thinning without damaging the back surface 10b of the front surface-side semiconductor layer 10, and it is not essentially necessary to maintain the residual region 60b or to etch so as to expose the back surface 50b of the insulating film 50 without damaging the back surface 50b.

FIG. 5 illustrates a process stage where p-type ions are implanted through the insulating layer 50. An implanting concentration of the p-type ions is set higher than an implanting concentration of the high-concentration n-type impurity introducing region 14. Further, the p-type ions are implanted by energy for making the p-type ions stay in a vicinity of a back surface 14e of the high-density n-type impurity introducing region 14. As a result, the vicinity of the back surface 14e of the high-density n-type impurity introducing region 14 becomes p-type. The region which has turned the p-type becomes a collector region 30. Reference number 14a in FIG. 5 represents a residual region of n-type impurities that remains even after the implantation of the p-type ions. The n-type impurity residual region becomes a buffer region 14a of the IGBT.

At steps in FIG. 5, the p-type ions are implanted with the insulating layer 50 remaining. When the ions are implanted in the state where the insulating layer 50 remains, contamination of the substrate caused by intrusion of metal into the substrate can be prevented. Further, the step in FIG. 5 illustrates a case where a semiconductor device to become an IGBT is being manufactured. When a semiconductor device having both the IGBT and a diode is manufactured, p-type ions are implanted into an area where the IGBT is to be formed so that a collector region is formed, and n-type ions are implanted into an area where the diode is to be formed so that a cathode region is formed. The ion implanting step shown in FIG. 5 may be executed after removal of the insulating film 50.

FIG. 6 illustrates a state that the insulating film 50 has been etched and removed. At this process stage, the etching is performed by using an etchant that etches the insulating film 50 (SiO₂) and hardly etches the front surface-side semiconductor layer 10 (Si monocrystal). When the back surface 10b of the front surface-side semiconductor layer 10 is exposed, the etching is ended. According to this, the thinning of the semiconductor substrate is completed.

According to the thinning method by selecting the SOI substrate as a substrate to be processed, and etching the 501 substrate using the etchant that etches the insulating film and hardly etches the front surface-side semiconductor layer so as to allow only the front surface-side semiconductor layer to remain,

(1) the insulating film may not remain on the thinned semiconductor substrate,

(2) the front surface-side semiconductor layer may not be thinned at the time of the thinning, and

(3) the back surface of the front surface-side semiconductor layer may not be damaged at the time of the thinning.

As a result of the above, a relationship that “the thickness of the thinned semiconductor substrate=the thickness of the front surface-side semiconductor layer of the SOI substrate” can be obtained.

The SOI substrate in which the thickness of the front surface-side semiconductor layer is controlled accurately to a constant value can be obtained. In the thinning method according to this embodiment, a variation in the thickness of the thinned semiconductor substrate can be repressed. Further, no scar is generated on the thinned surface.

FIG. 7 illustrates a process stage where a collector electrode 32 is formed on the back surface of the thinned SOI substrate 2 (namely, the back surface 10b of the front surface-side semiconductor layer 10).

FIG. 8 illustrates a process stage where the reinforcement member 70 has been peeled. FIG. 8 illustrates the SOI substrate 2 that is vertically inverted again. In the semiconductor device manufactured by the manufacturing method according to this embodiment, the semiconductor device in which a thickness L of the semiconductor substrate interposed in between the emitter electrode 24 and the collector electrode 32 is always controlled to be constant can be mass-produced.

An advantage of the suppression of the variation in the thickness of the thinned semiconductor substrate is described. FIG. 9 illustrates a relationship between the thickness of the semiconductor substrate and a short circuit tolerance. The semiconductor substrate is thicker toward a right side, and the short circuit tolerance is higher toward an upper side. The short circuit tolerance is a tolerance capacity until the semiconductor device is broken when an abnormally large current flows in the semiconductor device, and as the tolerated dose is higher, it is harder for the semiconductor device to be broken. The tolerance capacity is determined by an amount of heat generation and a heat transfer quantity, and a relationship is obtained such that as the semiconductor substrate is thicker, the short circuit tolerance is higher.

Reference symbol A in the drawing represents a lower limit value of the short circuit tolerance which is technically necessary for the semiconductor device. This means that the semiconductor substrate needs to be at least thicker than B. A distance between B and D represents a magnitude of a variation in the thickness of the semiconductor substrate according to the conventional manufacturing method (namely, in which the polishing and thinning are performed). Even if the variation is generated, the thickness which is equal to or more than B needs to be obtained. In the conventional manufacturing method, designing such that the thickness of the thinned semiconductor substrate is set to D is necessary, and if the designing is not conducted, the lower limit value A of the short circuit tolerance cannot be satisfied when the thickness of the semiconductor substrate varies. Contrary to this, a distance between B and C represents the magnitude of a variation in the thickness of the semiconductor substrate in the manufacturing method according to the embodiment (namely, the method of thinning the semiconductor substrate while allowing the front surface-side semiconductor layer of the SOI substrate to remain). As described above, it can be found that a design value of the thickness of the semiconductor substrate can be set to C because the variation in the thickness of the semiconductor substrate is reduced in the manufacturing method according to the embodiment. Even when the design value is reduced from I) to C, the lower limit value A of the short circuit tolerance can still be satisfied.

As one example, in the conventional method, the distance between B and D is 10 μm, and when B=114 μm, D=124 μm. In the embodiment, the distance between B and C becomes 1 μm, and C=115 μm. The design value of the thickness of the semiconductor substrate can be reduced from 124 μm to 115 μm.

FIG. 10 illustrates a relationship between the thickness of the semiconductor substrate and an on-voltage of the semiconductor device. The thickness of the semiconductor substrate is thicker toward the right side, and the on-voltage is higher toward the upper side. The on-voltage is a potential difference between an emitter electrode and a collector electrode at a time when the semiconductor device is on, and as the on-voltage is higher, a loss in the semiconductor device becomes larger. A relationship is provided herein that as the semiconductor substrate is thinner, the on-voltage is lower it may be confirmed that the thinning is important for improving performance of the semiconductor device. Reference symbol IF in the drawing represents the on-voltage in a case of the conventional design value D, and reference symbol E in the drawing represents the on-voltage in a case of the design value C in the manufacturing method according to the embodiment. Reference symbol G represents a reduction amount of the on-voltage in the manufacturing method according to the embodiment. Here, G/F represents an improvement rate in the manufacturing method according to the embodiment. It may be confirmed from this embodiment that the on-voltage is reduced, and the loss is reduced.

As one example, a ratio between an on-resistance in a case where the D=124 μm and an on-resistance in a case where D=115 μm, is 1.05:1.00. In this embodiment, since the variation in the thickness of the semiconductor substrate can be suppressed, the on-resistance can be reduced by 5%.

In order to reduce the on-voltage, it is effective that the thickness of the semiconductor substrate is made to be thin, as described above. As a downside to this, when the semiconductor substrate is made to be thin, an electric field to be applied to the back surface of the semiconductor substrate becomes strong, and a voltage-withstanding performance during an off state of the semiconductor device is easily deteriorated. When the semiconductor device is turned off, a depletion layer spreads from an interface between the body region 16 and the drift region 12a shown in FIG. 8. When the spread depletion layer reaches the collector region 30 or reaches a scratch generated on the back surface in the manufacturing step, the voltage-withstanding performance of the semiconductor device is deteriorated. The buffer region 14a prevents the depletion layer from further spreading, and prevents the voltage-withstanding performance from being deteriorated. However, when the electric field to be applied to the back surface becomes strong, the buffer region 14a is easily depleted, and it becomes easier for the depletion layer to reach the collector region 30 and/or the scratch on the back surface. Therefore, it is effective to thicken the buffer region 14a in order to prevent the deterioration of the voltage-withstanding performance. As the semiconductor substrate is made to be thinner, a need to thicken the buffer region 14a is further increased. In the conventional manufacturing method, after processing on the front surface is ended, the back surface is thinned, ions are implanted, and heat treatment is executed so that the buffer region 14a is manufactured. Since the heat treatment can be performed only within a range such that the structure of the front surface may not be damaged, it is difficult to thicken the buffer region 14a.

FIG. 11 illustrates relationships between a distance from the back surface and the impurity concentration, the relationships being obtained when a high-concentration impurity is introduced into the semiconductor substrate from the back surface. Specifically, FIG. 11 illustrates concentration profiles after the heat treatment is conducted after the implanting. When the semiconductor substrate is thinned, the heat treatment is conducted after the processing to the front surface side of the semiconductor substrate is completed, and therefore the heat treatment needs to be conducted only under a condition that the structure on the front surface side is not damaged. (3) of FIG. 11 represents a concentration profile obtained when the heat treatment is conducted by irradiating a laser to the back surface after ions are implanted. It can be found that the high-concentration region cannot be thickened. On the other hand, (2) represents a concentration profile obtained in the SOI substrate obtained by implanting ions into the semiconductor substrate before the attachment and then conducting heat treatment to it and then performing the attachment after the heat treatment. Since a temperature of the heat treatment is thus not restricted, the high-concentration region can be thickened. Further, an activating rate of the impurity is very high, and a defect hardly occurs in the buffer layer. For this reason, an increase in a leak current can be suppressed. Reference number (1) represents a concentration profile at a time of implanting protons. When the protons are implanted, a thick buffer region can be formed. When the proton is implanted, however, a defect easily occurs in the buffer region, and thus the leak current increases.

As shown in FIG. 1, when the SOI substrate 2 where the n-type impurity high-concentration introducing region 14 is formed on the back surface 10b of the front surface-side semiconductor layer 1 is used, it is possible to thin the semiconductor substrate so that the on-voltage can be lowered, and to thicken the buffer region so that the deterioration of the voltage-withstanding performance can be prevented, and a defect density of the buffer region is reduced so that the leak current can be suppressed. Further, the impurity concentration and the depth of the buffer layer can be freely adjusted. It is easy to obtain the concentration profile required by the semiconductor device.

In the conventional manufacturing method, namely, the thinning method using the mechanical polishing, scratches are easily generated on the thinned back surface of the semiconductor substrate. When the depletion layer reaches the scratches, the leak current of the semiconductor device undesirably increases. In this embodiment, since the back surface of the front surface-side semiconductor layer is exposed by the etching, the thinned back surface of the semiconductor substrate is less likely to be scratched. Even when a scratch is formed, as described above, an increase in the leak current can be efficiently prevented because a sufficient thickness of the buffer layer can be secured.

### Improved Embodiments

A thickness of a semiconductor substrate that affects a performance of a semiconductor device means a thickness in a range shown in FIG. 8 where the emitter electrode 24 and the collector electrode 32 face each other, and a thickness of the semiconductor substrate in a range where both of the emitter electrode 24 and the collector electrode 32 do not face does not affect the performance of the semiconductor device. In the improved technique, thinning is not performed in the range where both of the electrodes do not face and a back surface-side semiconductor layer and so on are allowed to remain, and a strength of the semiconductor substrate is secured with the remaining portion. The thickness after the thinning is controlled to be a constant value by using the front surface-side semiconductor layer in the range where the emitter electrode 24 and the collector electrode 32 face each other. The range where the emitter electrode 24 and the collector electrode 32 face each other is a region where a semiconductor structure, which is operated as an IGBT by an emitter region 18, a trench gate electrode 20, a body region 16, a drift region 12a, a buffer region 14a, and a collector region 30, is formed, and is referred to as an active region in this specification. The active region in this specification is a region where the semiconductor structure that functions as a semiconductor device is formed, and is distinguished from a region where a peripheral voltage withstanding structure is formed.

FIG. 12 illustrates, attention being focused on one semiconductor substrate including both an active region Q where an IGBT structure is formed and a peripheral region P where the peripheral voltage withstanding structure is formed, an embodiment in which a technique for removing a back surface-side semiconductor layer 60 and an insulating layer 50 and maintaining only a front surface-side semiconductor layer 10 so as to perform thinning is applied to the active region Q, whereas in the peripheral region P, the state of the substrate being thick is maintained by maintaining the back surface-side semiconductor layer 60 and the insulating layer 50. When an SOI substrate is viewed in plan, the peripheral region P surrounds a periphery of the active region Q. Dicing is performed along the peripheral region P after manufacturing, so that a plurality of IGBT chips is manufactured from one SOI substrate.

In FIG. 12, the regions that were explained with reference to FIG. 8 are denoted by the same reference numbers, and the overlapping descriptions are omitted. In FIG. 12, reference number 60P represents the back surface-side semiconductor layer 60 that is maintained in the peripheral region P, and reference number 50P represents the insulating layer 50 that is maintained in the peripheral region P. Contrary to this, a region 60Q represented by a virtual line is a region that was the back surface-side semiconductor layer 60 present in the active region Q and was removed by etching, and a region 50Q is a region that was the insulating layer 50 present on the active region Q and was removed by the etching. By adopting an etching technique together with a mask technique, not shown, a result that a limited region is etched and a part other than the limited region is not etched, can be obtained. FIG. 12 illustrates a result after a region selective etching, which is performed according to regions, such that the region. 60Q is etched to be removed, the region 60P is not etched to remain, the region 50Q is etched to be removed, and the region 50P is not etched to remain. The etching requires a longer time than the mechanical polishing. In the meantime, it is difficult by the mechanical polishing to thin a limited range, whereas it is possible by the etching to thin the limited range. Therefore, it is preferable that the entire back surface of the back surface-side semiconductor layer 60 is polished until a thickness represented by 60P in FIG. 12 is obtained, and thereafter the etching that is selectively performed according to regions is performed. Since the back surface-side semiconductor layer 60P having an enough thickness that can be etched within a practical time is caused to remain, the semiconductor substrate is hardly broken and hardly deflected, and thus can be easily handled.

FIG. 12 illustrates a process stage where, after the back surface-side semiconductor layer 60 was selectively etched in the active region Q, p-type ions are implanted from the back surface of the SOI substrate 2. The p-type ions are implanted by energy for making the p-type ions stay in a vicinity of a back surface 14b of an n-type impurity high-concentration introducing region 14. Since the back surface-side semiconductor layer 60P remaining in the peripheral region P serves as a mask, the p-type ions do not reach the front surface-side semiconductor layer 10 the p-type ions are implanted into the vicinity of the back surface 14b of the n-type impurity high-concentration introducing region 14 only in the active region Q. An implanted concentration of the p-type ions is made to be higher than an implanted concentration of the n-type impurities. As a result, the vicinity of the back surface 14b of the n-type high-concentration impurity introducing region 14 is converted to p-type. This region that has come to be of the p-type becomes a collector region 30b. The collector region 30b is formed only in the active region Q. In FIG. 12, reference number 14b represents a high-concentration region of the n-type impurity that remains even after the implanting of the p-type ions. The n-type impurity high-concentration region 14b becomes a buffer region. The buffer region 14b is formed in both the peripheral region P and the active region Q.

The ion implanting step shown in FIG. 12 may be performed after the insulating film 50Q is removed, or may be performed through the insulating film 50Q. According to the improved embodiment, the back surface-side semiconductor layer 60P that remains in the peripheral region P serves as a mask, and the collector region 30b can be formed only in the active region Q.

After the step in FIG. 12, a collector electrode 32 contacting the collector region 30b is formed. The collector electrode 32 is formed only in the region 60Q from which the back surface-side semiconductor layer was removed and in the region 50Q from which the insulating film 50 was removed.

FIG. 13 illustrates a process stage where the reinforcement member 70 has been removed thereafter (illustrates the substrate in a state of being vertically inverted). The regions that were described with reference to FIG. 8 are denoted by the same reference numbers, and the overlapped descriptions are omitted. FIG. 13 is an illustration enlarged more than FIG. 8, and a gate insulating film 36 and an inter-layer insulating film 34 are described.

According to a structure of FIG. 13, the following advantages may be obtained.

(1) Since the back surface-side semiconductor layer 60P and the insulating layer 50P that remain in the peripheral region P serve as reinforcement members, the strength of the semiconductor substrate can be improved and thus the semiconductor substrate can be easily handled.

(2) The collector region 30b is not formed in the peripheral region P, and holes are hardly implanted into the peripheral region P. When the holes are implanted into the peripheral region P, the holes concentrate in vicinity of a boundary between the peripheral region P and the active region Q during turn-off, and a breakdown resistance is reduced. The structure in FIG. 13 enables the breakdown resistance to be maintained high.

(3) There is a possibility that the holes may be implanted from the collector electrode 32 into the peripheral region P via the back surface-side semiconductor layer 60P remaining in the peripheral region P. However, since the insulating layer 50P remains in the peripheral region P, the implanting of holes may be prevented. This also contributes to the improvement of the breakdown resistance.

(4) When the semiconductor layer 10 of the semiconductor device is thinned, a short circuit tolerance is reduced. In this embodiment, since a thick back surface electrode 32 can be formed in the active region Q, the voltage withstanding tolerance is not reduced. In the peripheral region P, the thick back surface-side semiconductor layer 60P remains so as to prevent the decrease in the voltage withstanding tolerance. Although thermal conductivity of the insulating layer 50P is low, when its thickness is reduced to 1/107 or less of the thickness of the SOI substrate 2, effect of the low thermal conductivity is hardly exerted.

### Improved Second Embodiment

As shown in FIG. 14, a buffer region 14c and a collector region 30c may be spread over an entire region of a semiconductor substrate. By processing a back surface side of a front surface-side semiconductor layer 10, that is not yet to be attached to form an SOI substrate, so as to form the buffer region 14c and the collector region 30c, the structure in FIG. 14 can be realized. By executing the process of the back surface side at this process stage, impurity concentrations and diffusion depths of the buffer region 14c and the collector region 30c can be freely adjusted.

Also in this embodiment, carriers are likely to be implanted into the peripheral region P via the back surface-side semiconductor layer 60P remaining in the peripheral region P. However, since the insulating layer 50P remains in the peripheral region P, implantation of the carriers may be prevented as indicated by x marks in FIG. 14. This also contributes to the improvement of the breakdown resistance.

### Improved Third Embodiment

FIG. 15 illustrates a structure of a semiconductor device according to an improved third embodiment. The same regions that have been already described are denoted by the same reference numbers, and the overlapped descriptions are omitted. Only different aspects are described. The same is true in the following embodiments.

In a structure of FIG. 15, instead of the thinning over an entire region of the active region Q, back surface-side semiconductor layers 60Q and insulating layers 50Q are intermittently allowed to remain also in the active region Q. Describing from another viewpoint, in the active region Q, the back surface-side semiconductor layer and the insulating layer are removed to be thinned in a plurality of divided ranges. A collector electrode 32a is formed in the thinned ranges. By adjusting thicknesses of walls of the back surface-side semiconductor layers 60Q and the insulating layers 50Q that divide the thinned ranges, a result that an adjacent collector region 30b is made continuous can be obtained. This is because heat treatment is performed to cause diffusion in a process of forming the collector region 30b. It should be mentioned herein that an adjacent collector region may be discontinuous. When performance at turning-off is not satisfactory because of excessive implantation of the holes, it is advantageous to maintain the adjacent collector region in the discontinuous state. When the back surface-side semiconductor layers 60Q and the insulating layers 50Q are allowed to remain in the intermittent ranges in the active region Q, mechanical strength of the semiconductor substrate is further increased. An anisotropic etching may be employed when it is necessary for removing the back surface-side semiconductor layer and the insulating layer in the plurality of divided ranges. The anisotropic etching enables etching that bores the substrate deeply in a thickness direction of the semiconductor substrate.

### Improved Fourth Embodiment

FIG. 16 illustrates a structure of a semiconductor device according to an improved further embodiment. In FIG. 16, a plurality of guard rings is formed in the peripheral region P so that a withstand voltage may be secured. As shown in FIG. 15, a peripheral voltage withstanding structure may be realized by a RESURF structure,

### Improved Fifth Embodiment

In this embodiment, an n-type front surface-side semiconductor layer 10 is used. A characteristic of the IGBT is improved more in a combination of an n-type emitter region, a p-type body region an n-type drift region, and a p-type collector. On the other hand, a conductivity type of a back surface-side semiconductor layer 60 may be n-type, i-type, or p-type. FIG. 17 illustrates a case where a conductivity type of the front surface-side semiconductor layer 10 is opposite to a conductive type of a back surface-side semiconductor layer 60P.

### Improved Sixth Embodiment

In the above embodiments, the buffer regions 14a to 14c that spread over the entire region of the semiconductor substrate are implemented. Contrary to this, as shown in FIG. 18, a buffer region and a collector region may not be present in a peripheral region P. That is to say, a buffer region 14d and a collector region 30b may be formed only in an active region Q. In this case, an SOI substrate where an n-type impurity high-concentration introducing region 14 is not formed is used. The structure in FIG. 18 can be obtained by using the back surface-side semiconductor layer 60P that remains in the peripheral region P as a mask in the process stage of FIG. 12, and implanting n-type ions so as to form the buffer region 14d, and implanting p-type ions so as to form the collector region 30b.

The above has described the embodiments in detail. But they are considered as only illustrative, and thus do not limit the scope of claims. The technique described in the scope of claims includes all modifications and changes of concrete examples illustrated above.

Technical components described in this specification or illustrated in the drawings produce technical utility in every single one of them alone or various combinations of them, and thus are not limited to combinations of claims at a time of application. Further, the techniques illustrated in the specification or the drawings simultaneously accomplish a plurality of objects, and the technical utility is produced by accomplishing any one of the objects.

### EXPLANATIONS OF LETTERS OF NUMERALS

2: SOI substrate
2a: Front surface
2b: Back surface
10: Front surface-side semiconductor layer
10b: Back surface
12: N-type impurity low-concentration introducing region
12a: Drift region (n-type impurity low-concentration residual region)
14: N-type impurity high-concentration introducing region
14a: Buffer region (n-type impurity high-concentration residual region)
16: Body region (p-type impurity introducing region)
18: Emitter region
20: Trench gate electrode
22: Body contact region
24: Emitter electrode
26: Protective film
28: Peripheral voltage withstanding structure
30: Collector region (p-type impurity introducing region)
32: Collector electrode
50: Insulating layer
60: Back surface-side semiconductor layer
60a: Polished region
60b: Residual region
60c: Polished surface
70: Reinforcement member

1. A manufacturing method of a vertical semiconductor device, the method comprising:
executing a first process, which is to be performed on a front surface, to the front surface of a front surface-side semiconductor layer of an SOI substrate, the SOI substrate including the front surface-side semiconductor layer, an insulating layer, and a back surface-side semiconductor layer that are laminated in this order;
an etching a back surface of the SOI substrate after the first process, and removing the back surface-side semiconductor layer and the insulating layer in at least a part of an active region in which a semiconductor structure functioning as a semiconductor device is formed, so as to expose a back surface of the front surface-side semiconductor layer; and
executing a second process, which is to be performed on the back surface, on the back surface of the front surface-side semiconductor layer after the etching step.

2. The manufacturing method according to claim 1, further comprising:
thinning the back surface-side semiconductor layer by mechanically polishing the back surface of the SOI substrate, which is executed between the first process and the etching.

3. The manufacturing method according to claim 1, wherein
the etching includes removing the back surface-side semiconductor layer and the insulating layer in the active region to expose the back surface of the front surface-side semiconductor layer, and allowing the back surface-side semiconductor layer and the insulating layer in a region other than the active region to remain.

4. The manufacturing method according to claim 3, wherein
in the second process, the back surface-side semiconductor layer and the insulating layer that had been allowed to remain are used as a mask.

5. The manufacturing method according to claim 1, wherein
the SOI substrate, in which ions having a same conductivity type as the front surface-side semiconductor layer are introduced into a vicinity of the back surface of the front surface-side semiconductor layer, is used.

6. A vertical semiconductor device comprising:
an active region in which a semiconductor structure functioning as a semiconductor device is formed; and
a peripheral voltage withstanding region adjacent to the active region,
wherein an SOI substrate in which a front surface-side semiconductor layer, an insulating layer, and a back surface-side semiconductor layer that are laminated in this order remains in the peripheral voltage withstanding region, and
the insulating layer and the back surface-side semiconductor layer are removed in the active region.

7. The semiconductor device according to claim 6, wherein
the insulating layer and the back surface-side semiconductor layer are removed in a part of the active region.

8. The semiconductor device according to claim 6, wherein
a collector electrode is formed in a range where the insulating layer and the back surface-side semiconductor layer are removed.

9. The semiconductor device according to claim 6, wherein
a collector region is formed in a range where the insulating layer and the back surface-side semiconductor layer are removed.

10. The semiconductor device according to claim 6, wherein
a buffer region is formed in a range where the insulating layer and the back surface-side semiconductor layer are removed.
